(19) United States
(12) Patent Application Publication
(10) Pub. No.: US 2007/0020844 A1
(43) Pub. Date: Jan. 25, 2007

(54) Method for fabricating bit line of memory device

(75) Inventors: Yi-Nan Chen, Taipei (TW); Tzu-Ching Tsai, Taoyuan (TW)

Correspondence Address: QUINTERO LAW OFFICE, 1617 BROADWAY, 3RD FLOOR, SANTA MONICA, CA, 90404, US

(73) Assignee: NANYA TECHNOLOGY CORPORATION, TAOYUAN (TW)

(21) Appl. No.: 11/490,206

(22) Filed: Jul. 19, 2006

(30) Foreign Application Priority Data
Jul. 21, 2005 (TW) TW94124678

(51) Int. Cl. H01L 21/8242; H01L 29/94

(52) U.S. Cl. 438/253; 257/303; 438/262; 438/592

(57) ABSTRACT

A damascene process. A substrate covered by a dielectric layer and an overlying polysilicon masking layer with an opening exposing the underlying dielectric layer is provided. The exposed dielectric layer is etched to form a damascene opening therein and a portion of polysilicon masking layer remains on the dielectric layer. The remaining polysilicon masking layer is completely transformed into a metal polycide layer and then removed. A method for fabricating a bit line of a memory device is also disclosed.

### BACKGROUND

The invention relates to a memory device fabricating technology and in particular to a method for fabricating a bit line of a memory device.

A dynamic random access memory (DRAM) is a common semiconductor memory device widely employed in electronic products. In order to increase the density of the memory devices and improve performance thereof, the size of memory devices must be reduced. The fabrication of conductive plugs connected to the bit lines and disposed between the word lines, however, becomes more difficult as memory device geometries continue to decrease in size. Therefore, many self-aligned processes have been developed for bit line contact fabrication, which are useful for the fabrication of conductive plugs.

Such a self-aligned bit line contact is fabricated by a conventional damascene process using a polysilicon hard mask. Typically, the damascene process includes a step of forming a damascene opening, such as via hole, trench, or combination thereof, in a dielectric layer. A metal barrier layer and a metal layer are successively formed on the dielectric layer and fill the damascene opening. The excess metal layer and metal barrier layer are successively removed by polishing.

Metal polycide, however, is formed between the metal barrier layer and the polysilicon hard mask during fabrication of the bit line contact (C_{B}) of the memory device. The metal polycide is formed due to the existence of the polysilicon hard mask, and is very difficult to remove by subsequent polishing, such as chemical mechanical polishing (CMP), thus the metal polycide is called polysilicon residue. The polysilicon residue extends radially along the periphery of the contact to bit line, causing bit line leakage. If polysilicon residue extends to the neighboring bit line, a short circuit between the bit lines may occur, resulting in device failure.

### SUMMARY

A damascene process and a method for fabricating a bit line of a memory device are provided. An embodiment of a damascene process comprises providing a substrate covered by a dielectric layer. A polysilicon masking layer is formed on the dielectric layer, comprising an opening to expose the underlying dielectric layer. The exposed dielectric layer is etched to form a damascene opening therein and a portion of the polysilicon masking layer remains on the dielectric layer. The damascene opening is filled with a metal layer. The remaining polysilicon masking layer is completely transformed into a metal polycide layer. The metal polycide layer is then removed.

An embodiment of a method for fabricating a bit line of a memory device comprises providing a substrate comprising a memory array region and at least two gate structures therein. A dielectric layer is formed on the substrate and the gate structures. A polysilicon masking layer is formed on the dielectric layer, comprising an opening above the dielectric layer between the gate structures. The dielectric layer under the opening is etched to form a bit line contact therein, and a portion of the polysilicon masking layer remains on the dielectric layer. The bit line contact is filled with a tungsten layer. A titanium layer is formed on the remaining polysilicon masking layer and the tungsten layer, having a thickness greater than the remaining polysilicon masking layer. The substrate is annealed to completely transform the remaining polysilicon masking layer into a titanium polycide layer. The titanium polycide layer is removed by an etching solution comprising hydrofluoric acid.

### DESCRIPTION OF THE DRAWINGS

The invention will become more fully understood from the detailed description given hereinbelow and the accompanying drawings, given by way of illustration only and thus not intended to be limitative of the invention.

FIGS. 1A to 1G are cross-sections of an embodiment of a damascene process for fabricating a bit line.

### DETAILED DESCRIPTION

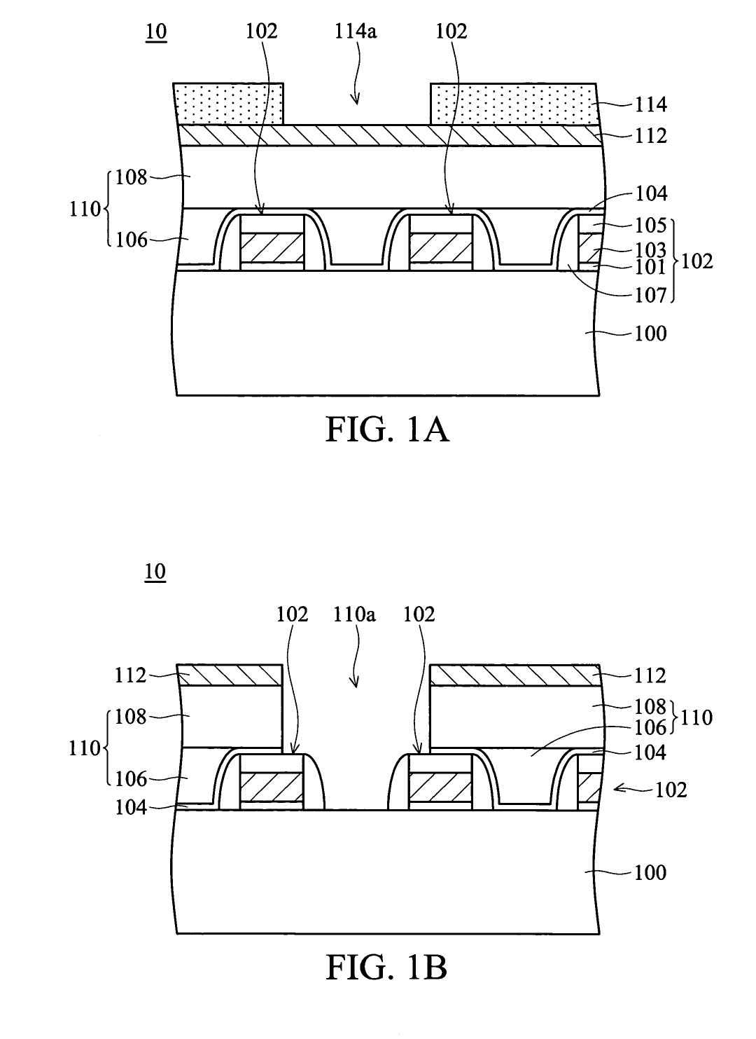

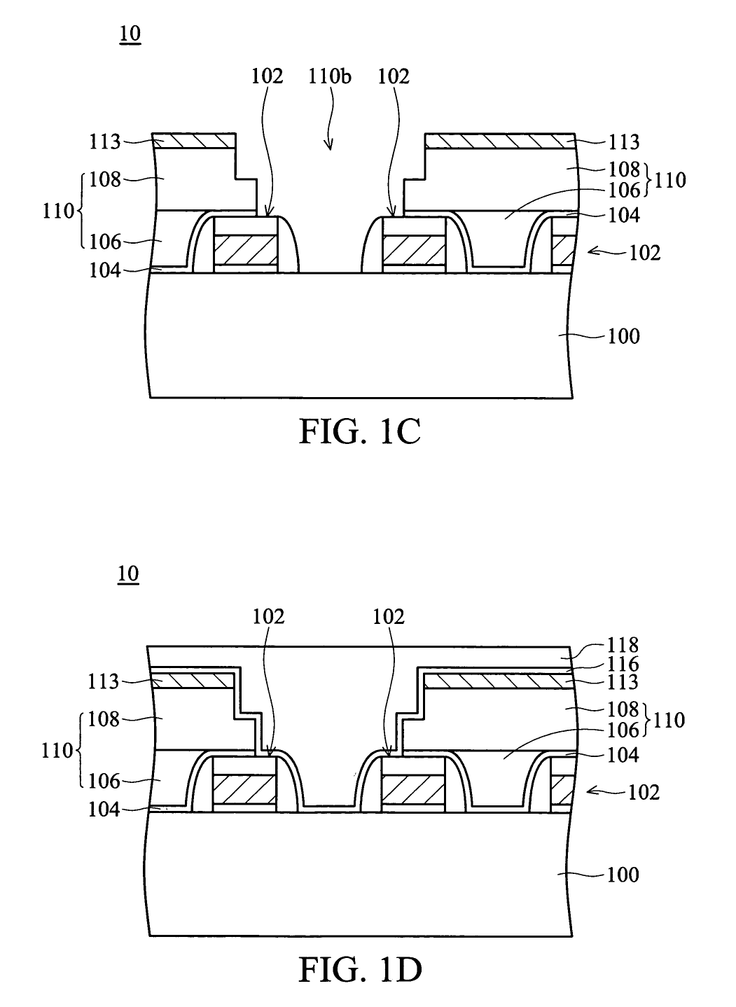

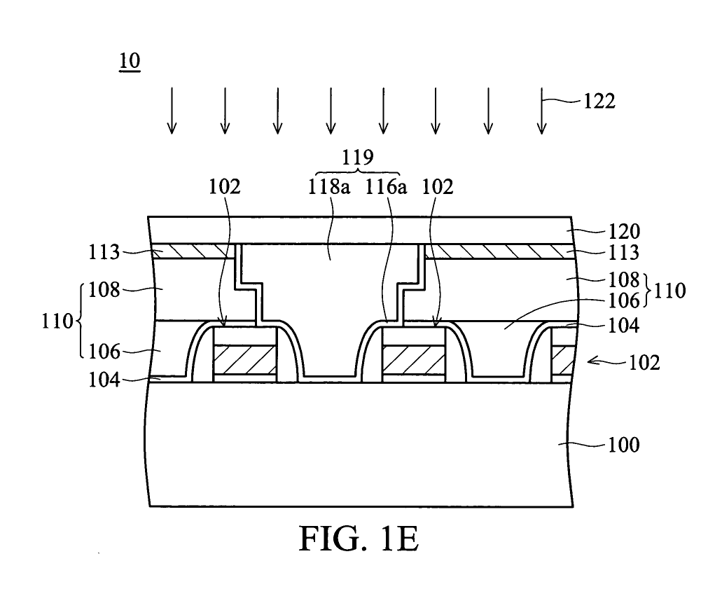

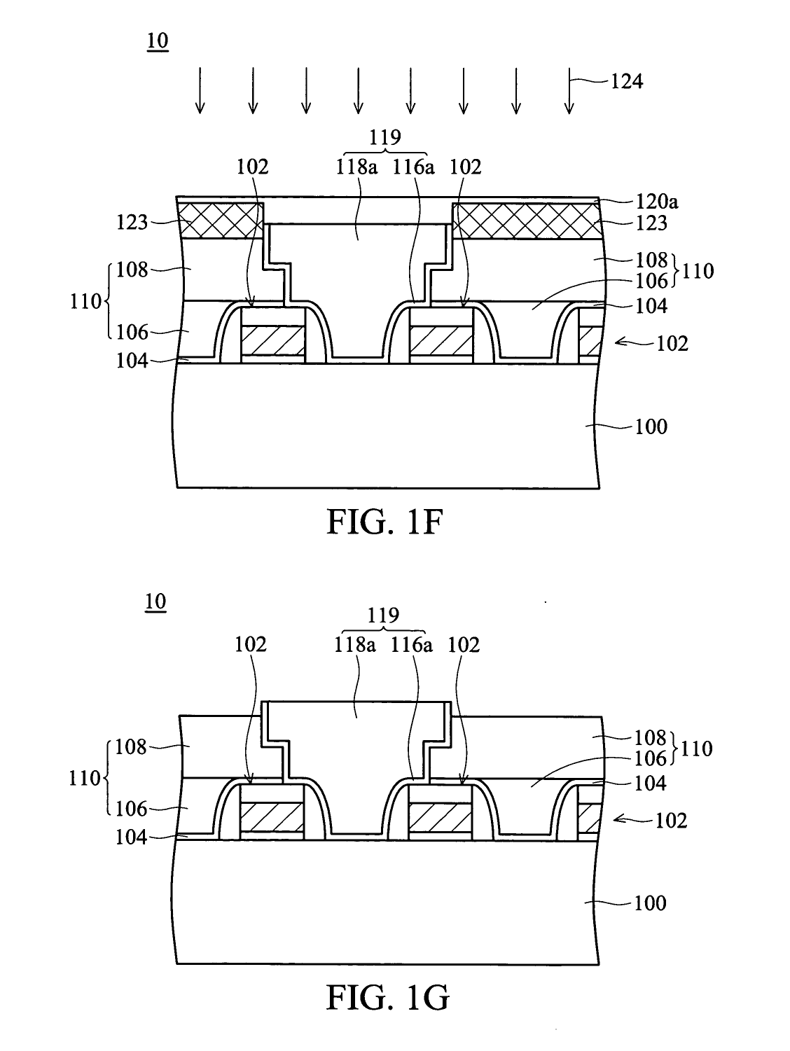

FIGS. 1A and 1G illustrate an exemplary embodiment of a damascene process for fabricating bit line for a memory device, such as DRAM. In FIG. 1A, a substrate 100, such as a silicon wafer, is provided. The substrate 100 may contain semiconductor devices, such as MOS transistors and capacitors, used in the memory devices. Here, in order to simplify the diagram, only a flat substrate is depicted. The substrate 100 comprises a memory array region 10. At least two gate structures 102 are formed on the substrate 100 of the memory array region 10. Typically, the gate structure 102 may comprise a gate dielectric layer 101, a gate electrode 103, a cap layer 105 and a gate spacer 107. The gate dielectric layer 101 may comprise silicon oxide formed by thermal oxidation. The gate electrode 103 may comprise a single polysilicon layer or a multiple layer comprising a polysilicon layer and an overlying metal polycide layer. The cap layer 105 and the gate spacer 107 may comprise silicon nitride.

Next, a liner 104, such as a silicon nitride layer, may optionally line the surfaces of the gate structures 102 and the substrate 100. A dielectric layer (not shown), such as a boro-phospho-silicate glass (BPSG) layer formed by chemical vapor deposition (CVD), is formed on the liner 104 and fills the gaps between the gate structures 102. Next, an etch back process, such as chemical mechanical polishing (CMP), is performed on the dielectric layer using the liner 104 as a stop layer, to leave a portion of the dielectric layer 106 between the gate structures 102. Another dielectric layer 108, such as an oxide layer formed by tetraethyl orthosilicate (TEOS) using CVD technology. Here, the dielectric layers 106 and 108 serves as an interlayer dielectric (ILD) layer 110. In some embodiments, the ILD layer 110 may comprise a single layer comprise BPSG.

A polysilicon layer 112 is formed on the ILD layer 110 and a photoresist layer (not shown) is subsequently applied thereon. In this embodiment, the polysilicon layer 112 has a thickness of about 750 Å to 950 Å and serves as a masking layer (hard mask). The photoresist layer is patterned by conventional lithography to form a photoresist pattern layer 114 with at least one opening 114a exposing the polysilicon masking layer 112, in which the opening 114a is above the dielectric layer 110 between the gate structures 102 in the memory region 10.

The opening 114a is transferred into the polysilicon masking layer 112 using the photoresist pattern layer 114 as an etch mask. Next, the ILD layer 110 and the liner 104 under the opening in the polysilicon masking layer 112 are successively etched to form a contact 110a, exposing the substrate 100. The photoresist pattern layer 114 is then removed, as shown in FIG. 1B.

Another photoresist pattern layer (not shown) is formed on the polysilicon masking layer 112 by conventional lithography, which comprises an opening wider than the contact 110a for definition of a bit line. Next, the polysilicon masking layer 112 is etched to transfer the wider opening thereinto. After removal of the photoresist pattern layer, the dielectric layer 108 is etched using the polysilicon masking layer 112 as an etch mask, to form a bit line contact 110b therein, and a portion of the polysilicon masking layer 113 remains on the dielectric layer 108, as shown in FIG. 1C.

In FIG. 1D, a metal barrier layer 116 is conformally formed on the remaining polysilicon masking layer 113 and the sidewall and bottom of the bit line contact 110b. The metal barrier layer 116 may comprise titanium, tantalum, titanium nitride, tantalum nitride, Ti—W alloy, tungsten nitrides or combination thereof. In this embodiment, the metal barrier layer 116 is preferably a composite layer of a titanium layer and an overlying titanium nitride layer. A metal layer 118, such as a tungsten layer is subsequently formed on the metal barrier layer 116 by CVD and fills the bit line contact 110b. Since the titanium-containing barrier layer 116 contacts the remaining polysilicon masking layer 113, a titanium polycide layer (not shown) is formed therebetween.

In FIG. 1E, the excess metal layer 118 and metal barrier layer 116 on the ILD layer 110 may be removed by CMP using the remaining polysilicon masking layer 113 as a stop layer, thus, a bit line 119 with a conductive plug is formed by the left metal layer 118a and metal barrier layer 116a in the bit line contact 110b. The titanium polycide layer (polysilicon residue) on the remaining polysilicon masking layer 113, however, is difficult to completely remove by CMP, easily resulting in bit line leakage. If the polysilicon residue extends across the neighboring bit line, a short circuit between bit lines may occur, causing the memory device to fail. In order to solve such problems, in this embodiment, a metal layer 120, such as titanium, tantalum, cobalt, or nickel, is formed on the remaining polysilicon masking layer 113 and the bit line 119 by conventional deposition, for example, PVD, after the bit line 119 formed. Annealing 122 is performed on the substrate 100 shown in FIG. 1E, thereby the remaining polysilicon masking layer 113 under the metal layer 120 is completely transformed into a metal polycide layer 123, such as titanium polycide, as shown in FIG. 1F. The annealing 122 is performed at a temperature above 300° C. The nonreacted metal layer 120a remains on the metal polycide layer 123 and the bit line 119, as shown in FIG. 1F. In this embodiment, the metal layer 120 may be thicker than the remaining polysilicon masking layer 113 in order to completely transform the remaining polysilicon masking layer 113 into the metal polycide layer 123. For example, the metal layer 120 is about two to three times the thickness of the remaining polysilicon masking layer 113.

As shown in FIG. 1G, the remaining metal layer 120a and the underlying metal polycide layer 123 are completely removed to expose the surfaces of the bit line 119 and the ILD layer 110. In this embodiment, the remaining metal layer 120a and the underlying metal polycide layer 123 are removed by wet etching 124 (as shown in FIG. 1F). Such a wet etching 124 utilizes an etching solution comprising sulfuric acid (H₂SO₄), hydrogen peroxide (H₂O₂), and hydrofluoric acid (HF), in which the concentration of sulfuric acid in the etching solution is in a range of 6% to 26% and that of hydrofluoric acid in the etching solution about 8 ppm.

According to the invention, since the polysilicon hard mask has been completely transformed into the metal polycide layer and removed by wet etching, there is no polysilicon residue to induce electrical connection between bit lines. Accordingly, bit line leakage or a short circuit between bit lines can be improved, thereby increasing memory device reliability.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A damascene process, comprising:
providing a substrate covered by a dielectric layer;
forming a polysilicon masking layer on the dielectric layer, comprising an opening to expose the underlying dielectric layer;
etching the exposed dielectric layer to form a damascene opening therein and leave a portion of the polysilicon masking layer on the dielectric layer;
filling the damascene opening with a metal layer;
completely transforming the remaining polysilicon masking layer into a metal polycide layer; and
removing the metal polycide layer.

2. The damascene process as claimed in claim 1, wherein the metal polycide layer is a titanium polycide layer.

3. The damascene process as claimed in claim 2, wherein the formation of the titanium polycide layer comprises:
forming a titanium layer on the remaining polysilicon masking layer and the metal layer; and
completely transforming the remaining polysilicon masking layer into the titanium polycide layer by annealing.

4. The damascene process as claimed in claim 3, wherein the annealing is performed at a temperature of above 300° C.

5. The damascene process as claimed in claim 2, wherein the titanium polycide layer is removed by an etching solution comprising sulfuric acid, hydrogen peroxide, and hydrofluoric acid.

6. The damascene process as claimed in claim 2, wherein the concentration of sulfuric acid in the etching solution is in a range of 6% to 26%.

7. The damascene process as claimed in claim 1, further forming a metal barrier layer on the surface of the damascene opening and between the metal layer and the dielectric layer.

8. The damascene process as claimed in claim 1, wherein the metal barrier layer comprises a titanium layer and an overlying titanium nitride layer.

9. The damascene process as claimed in claim 1, wherein the dielectric layer comprises oxide formed by tetraethyl orthosilicate (TEOS).

10. The damascene process as claimed in claim 1, wherein the metal layer comprises tungsten.

11. The damascene process as claimed in claim 1, wherein the metal layer is about two to three times the thickness of the remaining polysilicon masking layer.

12. A method for fabricating a bit line of a memory device, comprising:
providing a substrate, comprising a memory array region and at least two gate structures therein;
forming a dielectric layer on the substrate and the gate structures;
forming a polysilicon masking layer on the dielectric layer, comprising an opening above the dielectric layer between the gate structures;
etching the dielectric layer under the opening to form a bit line contact therein and leaving a portion of the polysilicon masking layer on the dielectric layer;
filling the bit line contact with a tungsten layer;
forming a titanium layer on the remaining polysilicon masking layer and the tungsten layer, having a thickness thicker than the remaining polysilicon masking layer;
annealing the substrate to completely transform the remaining polysilicon masking layer into a titanium polycide layer; and
removing the titanium polycide layer by an etching solution comprising hydrofluoric acid.

13. The method as claimed in claim 12, further forming a metal barrier layer on the surface of the bit line contact and between the tungsten layer and the dielectric layer.

14. The method as claimed in claim 13, wherein the metal barrier layer comprises a titanium layer and an overlying titanium nitride layer.

15. The method as claimed in claim 12, wherein the dielectric layer comprises boro-phospho-silicate glass (BPSG) and oxide formed by tetraethyl orthosilicate (TEOS).

16. The method as claimed in claim 12, wherein the titanium layer is about two to three times the thickness of the remaining polysilicon masking layer.

17. The method as claimed in claim 12, wherein the substrate is annealed at a temperature of above 300° C.

18. The method as claimed in claim 12, wherein the etching solution further comprises sulfuric acid and hydrogen peroxide.

19. The method as claimed in claim 18, wherein the concentration of sulfuric acid in the etching solution is in a range of 6% to 26% and that of hydrofluoric acid in the etching solution about 8 ppm.
